(19) United States
(12) Patent Application Publication
(10) Pub. No.: US 2026/0322066 A1
(43) Pub. Date: Oct. 15, 2026

(54) SYSTEMS, APPARATUSES, AND METHODS FOR ADJUSTABLE REFERENCE CONTROL

(71) Applicant: Quantinuum LLC, Broomfield, CO (US)

(72) Inventor: Bruce Gregory Tiemann, Longmont, CO (US)

(21) Appl. No.: 19/629,470

(22) Filed: Mar. 26, 2026

Related U.S. Application Data
(60) Provisional application No. 63/789,070, filed on Apr. 15, 2025.

(51) Int. Cl. H01S 3/137; G01J 9/00; H01S 3/13

(52) U.S. Cl. CPC H01S 3/137; G01J 9/00; H01S 3/1305

(57) ABSTRACT

Systems, methods, and apparatus for adjustable reference control are provided. An example includes: a controlled device generating a controlled output based at least on a control signal; an instrument device receiving the controlled output and generating an instrument output; a measurement device measuring the controlled output at a measurement rate and a first accuracy and generating a measurement output signal. There is also that: generates an error signal at an error signal update rate and a second accuracy; generates a setpoint signal based at least on the measurement output signal; and generate the control signal to control the controlled device based at least on the at least a portion of the error signal that is monotonic and the setpoint signal. The error signal update rate is faster than the measurement rate and the first accuracy is more accurate than the second accuracy.

### CROSS-REFERENCE TO RELATED APPLICATION(S)

This application claims the benefit of U.S. Provisional Application No. 63/789,070, filed Apr. 15, 2025, the entire contents of which is incorporated by reference herein.

### TECHNOLOGICAL FIELD

Example embodiments of the present disclosure relate generally to adjustable reference control, particularly to adjustable reference controls of a laser beam in a quantum computing system that is stabilized with an etalon.

### BACKGROUND

Quantum computing systems utilize laser beams stabilized at specific frequencies. The stabilization to these frequencies is important for performing operations on qubits of the quantum computing system. If the laser is off frequency by a small amount, then the quantum computer is unable to function. Conventionally stabilized lasers are not only expensive but are also extremely sensitive to their environment and, thus, difficult to control at an absolute frequency. For example, small fluctuations in temperature that last for very short periods of time cause fluctuations in conventionally stabilized laser beams. Such fluctuations are unacceptable, particularly in quantum computing applications.

The inventor has identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to systems, apparatuses, and methods for adjustable reference control.

In accordance with some embodiments of the present disclosure, an example apparatus is provided. The example apparatus may comprise: a controlled device configured to generate a controlled output based at least on a control signal; an instrument device configured to receive the controlled output and to generate an instrument output based on the controlled output; a measurement device configured to measure the controlled output at a measurement rate and a first accuracy and to generate a measurement output signal; a control system to control the controlled device and configured to: generate an error signal at an error signal update rate and a second accuracy based at least on the instrument output, wherein at least a portion of the error signal is monotonic, wherein the error signal update rate is faster than the measurement rate, and wherein the first accuracy is more accurate than the second accuracy; generate a setpoint signal based at least on the measurement output signal, wherein the setpoint signal is associated with an offset related to the error signal; and generate the control signal to control the controlled device based at least on the at least a portion of the error signal that is monotonic and the setpoint signal.

In some embodiments, the controlled device is a laser; the controlled output is a laser beam; the control signal is a PDH lock signal; the instrument device is an etalon; the instrument output based on the controlled output is a stabilized laser beam; the measurement device is a wavemeter; the measurement output signal is a first wavemeter signal associated with a wavelength of the laser beam; the control system is comprised of a PDH circuitry, a PDH setpoint servo, a PDH servo; PDH circuitry of the control system is configured to generate the error signal of a PDH error signal; the PDH setpoint servo of the control system is configured to generate the setpoint signal of a PDH setpoint signal; and the PDH servo of the control system is configured to generate the control signal of the PDH lock signal based at least on the portion of the PDH error signal that is monotonic and the PDH setpoint signal.

In some embodiments, the PDH circuitry is comprised of: a diplexer circuitry configured to receive the stabilized laser beam from the etalon and diplex the stabilized laser beam into a plurality of signals including a diplexed RF signal; and a PDH controller configured to receive the diplexed RF signal and generate the PDH error signal.

In some embodiments, to adjust the PDH lock signal is based at least on one or more changes in the PDH setpoint signal associated with adjusting the offset of a PDH setpoint within a linear region of the portion of the PDH error signal that is monotonic.

In some embodiments, the apparatus further comprises a temperature controller configured to control a temperature of the environment of the etalon.

In some embodiments, the temperature controller is configured to control the temperature of the environment of the etalon based at least on a temperature setpoint signal; and the temperature setpoint signal is generated by a temperature setpoint servo based at least on a second wavemeter signal generated by the wavemeter.

In some embodiments, the apparatus further comprises a frequency generator configured to generate a frequency signal; and the laser is further configured to generate the laser beam also based at least on the frequency signal.

In accordance with some embodiments of the present disclosure, an example system is provided. The example system may comprise: an apparatus to receive an instrument output; a controlled device configured to generate a controlled output based at least on a control signal; an instrument device configured to receive the controlled output and to generate an instrument output based on the controlled output; a measurement device configured to measure the controlled output at a measurement rate and a first accuracy and to generate a measurement output signal; a control system to control the controlled device and configured to: generate an error signal at an error signal update rate and a second accuracy based at least on the instrument output, wherein at least a portion of the error signal is monotonic, wherein the error signal update rate is faster than the measurement rate, and wherein the first accuracy is more accurate than the second accuracy; generate a setpoint signal based at least on the measurement output signal, wherein the setpoint signal is associated with an offset related to the error signal; and generate the control signal to control the controlled device based at least on the at least a portion of the error signal that is monotonic and the setpoint signal.

In some embodiments, the system is a quantum computing system; the apparatus is a confinement apparatus; the controlled device is a laser; the controlled output is a laser beam; the control signal is a PDH lock signal; the instrument device is an etalon; the instrument output based on the controlled output is a stabilized laser beam; the measurement device is a wavemeter; the measurement output signal is a first wavemeter signal associated with a wavelength of the laser beam; the control system is comprised of a PDH circuitry, a PDH setpoint servo, a PDH servo; PDH circuitry of the control system is configured to generate the error signal of a PDH error signal; the PDH setpoint servo of the control system is configured to generate the setpoint signal of a PDH setpoint signal; the PDH servo of the control system is configured to generate the control signal of the PDH lock signal based at least on the portion of the PDH error signal that is monotonic and the PDH setpoint signal; and the PDH servo is further configured to adjust the PDH lock signal based at least on one or more changes in the PDH setpoint signal associated with changes in the wavemeter signal, and an adjustment to the PDH lock signal is associated with a fluctuation in an environment the etalon is located in.

In some embodiments, the PDH circuitry is comprised of: a diplexer circuitry configured to receive the stabilized laser beam from the etalon and diplex the stabilized laser beam into a plurality of signals include a diplexed RF signal; and a PDH controller configured to receive the diplexed RF signal and generate the PDH error signal.

In some embodiments, to adjust the PDH lock signal based at least on one or more changes in the PDH setpoint signal is associated with adjusting the offset of a PDH setpoint within a linear region associated with a linear response of the stabilized laser beam to the adjustment.

In some embodiments, the system further comprises a temperature controller configured to control a temperature of the environment of the etalon.

In some embodiments, the temperature controller is configured to control the temperature of the environment of the etalon based at least on a temperature setpoint signal; and the temperature setpoint signal is generated by a temperature setpoint servo based at least on a second wavemeter signal generated by the wavemeter.

In some embodiments, the system further comprises a frequency generator configured to generate a frequency signal; and the laser is further configured to generate the laser beam also based at least on the frequency signal.

In accordance with some embodiments of the present disclosure, an example method is provided. The example method may comprise: generating, with a controlled device, a controlled output based at least on a setpoint in a control signal; generating, with an instrument device, an instrument output based at least on the controlled output; generating, with a measurement device, a measurement output signal associated with a controlled variable of the controlled device output, wherein the measurement output signal has a measurement rate and a first accuracy; generating, with a control system, an error signal based at least on the instrument output, wherein the error signal has an error signal update rate and a secondary accuracy, wherein at least a portion of the error signal is monotonic, wherein the error signal update rate is faster than the measurement rate, and wherein the first accuracy is more accurate than the second accuracy; generating, with the control system, a setpoint signal based at least on the measurement output signal, wherein the setpoint signal is associated with an offset related to the error signal; and generating, with the control system, the control signal based at least on the error signal and the setpoint signal.

In some embodiments, the controlled device is a laser; the controlled output is a laser beam; the control signal is a PDH lock signal; the instrument device is an etalon; the instrument output based at least on the controlled output is a stabilized laser beam; the measurement device is a wavemeter; the measurement output signal is a first wavemeter signal associated with a wavelength of the laser beam; the control system is comprised of a PDH circuitry, a PDH setpoint servo, a PDH servo; generating the error signal is generating, by the PDH circuitry, the error signal of a PDH error signal; generating the setpoint signal is generating, by the PDH setpoint servo, the setpoint signal of a PDH setpoint signal; generating the control signal is generating, by the PDH servo, the control signal of the PDH lock signal based at least on the portion of the PDH error signal that is monotonic and the PDH setpoint signal; and the method further comprises: adjusting, by the PDH servo, the PDH lock signal based at least on one or more changes in the PDH setpoint signal associated with changes in the wavemeter signal, an adjustment to the PDH lock signal is associated with a fluctuation in an environment the etalon is located in.

In some embodiments, the PDH circuitry is comprised of a diplexer circuitry and a PDH controller; and the method further comprises: diplexing, with the diplexer circuitry, the stabilized laser beam from the etalon into a plurality of signals including a diplexed RF signal; and generating, with the PDH controller, the PDH error signal based as least one the diplexed RF signal.

In some embodiments, adjusting the PDH lock signal is based at least on one or more changes in the PDH setpoint signal associated with adjusting the offset of a PDH setpoint within a linear region associated with a linear response of the stabilized laser beam to the adjustment.

In some embodiments, the method further comprises controlling, with a temperature controller, a temperature of the environment of the etalon.

In some embodiments, controlling the temperature is based at least on a temperature setpoint signal generated by a temperature setpoint servo based at least on a second wavemeter signal generated by the wavemeter.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

Having thus described certain example embodiments of the present disclosure in general terms, reference will now be made to the accompanying drawings, which are not necessarily drawn to scale, and wherein:

FIG. 1 illustrates a schematic diagram of an example quantum computing system comprising a quantum system controller in accordance with one or more embodiments of the present disclosure;

FIG. 2 illustrates a schematic diagram of an optical package in accordance with one or more embodiments of the present disclosure;

FIG. 3 illustrates a schematic diagram of a PDH circuitry in accordance with one or more embodiments of the present disclosure;

FIG. 4 illustrates a graph of curves for PDH error versus optical detuning in accordance with one or more embodiments of the present disclosure;

FIG. 5 illustrates a flowchart of example operations for controlling a laser beam in accordance with one or more embodiments of the present disclosure;

FIG. 6 illustrates a schematic diagram of a controller in accordance with one or more embodiments of the present disclosure; and

FIG. 7 illustrates a schematic diagram of an example classical computing entity in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

### Overview

Various embodiments of the present disclosure are directed to improved adjustable reference control. Various embodiments include systems, apparatuses, and methods for providing the improved adjustable reference control, particularly in quantum computing applications. It will be appreciated that while embodiments described herein may be in the context of optical frequencies, various embodiments of the present disclosure provide for adjustable reference control in other applications that may use frequencies outside the optical domain.

Additionally, according to various embodiments of the present disclosure, the method described herein may be usable when the error signal does not correspond to a frequency, including in ways that would be understood by one skilled in the art in view of the present disclosure.

In quantum computing applications, controlling the temperature of an optical assembly is important. The temperature of an optical assembly is related to how sensitivity a laser beam that may be generated is to variations. The temperature of the optical assembly may, however, fluctuate based at least on temperature fluctuations in an environment. For example, a door may open and let in colder or warmer air. Controlling the temperature to such a specificity required by exemplary applications is problematic because, among other things, thermal adjustments to an environment are slow. In an example quantum computing application, a temperature may be required to be control to within a range of 300 microKelvin. Temperature fluctuations outside such a range may cause a stabilized laser beam to change frequency such that the laser beam is no longer stabilized on a frequency required to perform operations of the application (e.g., the laser beam may not be stabilized sufficiently to cause execution of a quantum circuit). This is referred to as optical detuning. While an optical package may have many components, there are a few described further herein that are examples of how a laser beam generated by an optical package is sensitive to variations.

Optical packages may include a laser that is stabilized by an etalon. An etalon has an optical cavity that is used for locking a laser beam to a specific frequency based at least on a stable resonance of the etalon. When a temperature fluctuation occurs, the etalon's resonance may change and/or the frequency of the laser beam output by the etalon changes.

Improvements over conventional locking lasers provided by the present disclosure include embodiments that provide a faster, smaller, and simpler system that allows for dynamically adjustable references for stabilized lasers by using dynamic electrical tuning for controlling the laser. The dynamic electrical tuning of the present disclosure allows for faster control than thermal tuning of conventional systems. Various embodiments may also be cheaper than conventional systems.

The dynamic electrical tuning provides for adjustable reference control. In various embodiments, the electrical tuning includes measuring the frequency of the laser beam generated by a laser and measuring the stabilized laser beam output by the etalon for a PDH (Pound-Drever-Hall) error. The PDH error is how far a laser frequency is from a resonance frequency of target frequency, particularly the resonant frequency of an optical cavity. A PDH setpoint is a target value for the PDH error signal that corresponds to a desired operating condition(s). In conventional systems, the PDH setpoint is set during calibration and does not change (e.g., it is locked to a 0 value). While conventional systems use the PDH error in conjunction with monitoring the detuning of a laser beam from a specific frequency, the present disclosure provides for adjustment of the PDH setpoint in addition to using the PDH error to determine optical detuning. This provides for an electrical adjustment that has much faster control when generating a stabilized laser beam. By using the PDH error and an adjustable or floating PDH setpoint, the optical detuning of the laser may be reduced and, thus, the stabilized laser beam may be controlled at a faster rate to maintain the frequency required for minimizing optical detuning.

For example, a quantum computing system may require that a laser be locked to an optical frequency in the THz range. A center frequency may be 500 THz with a range of +/−1 MHz. To stay within an acceptable range of variation to this center frequency, the temperature control of the etalon of the optical package needs to be controlled to +/−300 microKelvin to provide for frequency stability of 1 MHz. This is an extremely narrow range of temperatures. Thermally controlling the temperature does not respond to any temperature fluctuations as quickly as electrical control.

Various embodiments herein dynamically adjust or “float” the PDH setpoint up or down according to a more accurate but slow reference (e.g. wavemeter) to ensure that the high-bandwidth lock remains at the accurate frequency irrespective of temperature control. Dynamically adjusting the PDH setpoint allows for what would otherwise be a range of optical detuning values to be acceptable. This adjustable control of the PDH setpoint provides for adjustable tuning of the laser frequency to address the fluctuations experienced by an etalon. With such dynamic adjustments, even when the temperature of the etalon fluctuates slightly it is still possible to lock the laser tightly to the correct frequency.

### Exemplary Systems, Apparatuses, and Methods

The embodiments of the present disclosure herein include systems, apparatuses, and methods for adjustable reference control described, which may be implemented in various embodiments. An exemplary embodiment includes a quantum computing environment.

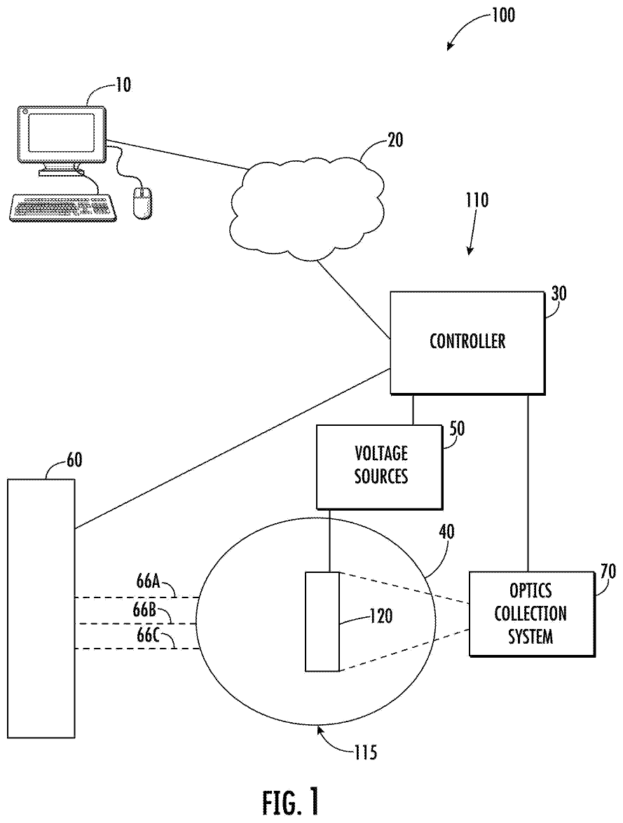

FIG. 1 is a schematic diagram of an example quantum computing environment comprising quantum computing system 100 where the quantum processor comprises an atomic object confinement apparatus 120 (e.g., an ion trap and/or the like) having a plurality of atomic objects (e.g., atoms, ions, and/or the like) confined therein, in accordance with an example embodiment. While various embodiments of the present disclosure are described herein, such as with quantum computing system 100, it will be readily appreciated that not all embodiments are expressly described and embodiments may include or be directed to different applications beyond those expressly described. Thus it will also be appreciated that various embodiments may include additional or alternative components and/or circuitries, the described components and/or circuitries may be alternatively arranged, and/or the one or more of the described components and/or circuitries may be omitted.

In various embodiments, the quantum computing system 100 comprises a computing entity 10 and a quantum computer 110. In various embodiments, the quantum computer 110 comprises a quantum system controller 30, which may be referred to as controller 30, and a quantum processor 115. In various embodiments, the quantum system controller 30 is configured, programmed, and/or the like to control the quantum processor 115. In an example embodiment, the quantum processor 115 comprises a plurality of qubits (e.g., data qubits that may be organized into logical qubits, ancilla qubits, and/or the like). In various embodiments, the quantum computer 110 includes or communicates with databases (not shown) described herein. For example, the databases may be stored by one or more computing entities 10 that are in communication with the controller 30 via one or more wired and/or wireless networks 20 and/or stored by memory local to the controller 30.

In various embodiments, the quantum processor 115 comprises means for controlling the evolution of quantum states of the qubits. For example, in an example embodiment, the quantum processor 115 comprises a cryostat and/or vacuum chamber 40 enclosing a confinement apparatus 120 (e.g., an ion trap), one or more manipulation sources 60, one or more voltage sources 50, and/or one or more optics collection systems 70. For example, the cryostat and/or vacuum chamber 40 may be a temperature and/or pressure-controlled chamber. In an example embodiment, the manipulation signals generated by the manipulation sources 60 are provided to the interior of the cryostat and/or vacuum chamber 40 (where the atomic object confinement apparatus 120 is located) via corresponding optical paths 66 (e.g., 66A, 66B, 66C). In an example embodiment, the one or more manipulation sources 60 may comprise one or more lasers (e.g., optical lasers, microwave sources, and/or the like). In various embodiments, the manipulation sources 60 may include or be included in one or more optical packages. In various embodiments, the one or more manipulation sources 60 are configured to manipulate and/or cause a controlled quantum state evolution of one or more atomic objects within the confinement apparatus. In various embodiments, the atomic objects within the atomic confinement apparatus (e.g., ions trapped within an ion trap) act as the data qubits and/or ancilla qubits of the quantum processor 115 of the quantum computer 110. For example, in an example embodiment, wherein the one or more manipulation sources 60 comprise one or more lasers, the lasers may provide one or more laser beams to atomic objects trapped within the confinement apparatus 120 within the cryostat and/or vacuum chamber 40. For example, the manipulation sources 60 may generate and/or provide laser beams configured to ionize atomic objects, initialize atomic objects within the defined two state qubit space of the quantum processor, perform gates one or more qubits of the quantum processor, read a quantum state of one or more qubits of the quantum processor, and/or the like.

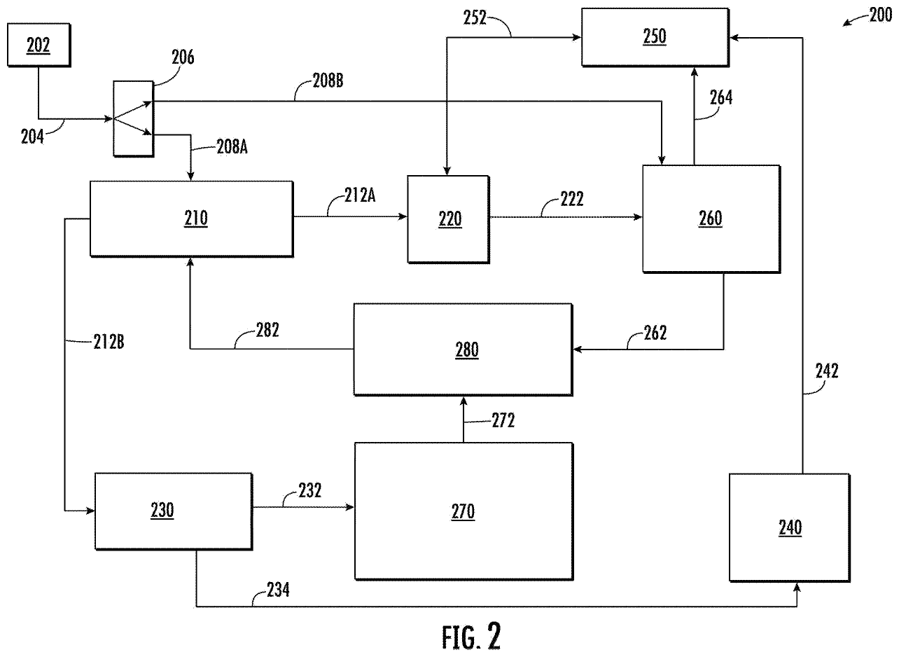

In various embodiments, the quantum computer 110 comprises an optics collection system 70 configured to collect and/or detect photons generated by qubits (e.g., during reading procedures, such as measurement operations). The optics collection system 70 may comprise one or more optical elements (e.g., lenses, mirrors, waveguides, fiber optics cables, and/or the like) and one or more photodetectors. In various embodiments, the photodetectors may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the qubits of the quantum computer 110. In various embodiments, the detectors may be in electronic communication with the quantum system controller 30 via one or more A/D converters 225 (see FIG. 2) and/or the like.

In various embodiments, the quantum computer 110 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding potential generating elements (e.g., electrodes) of the confinement apparatus 120, in an example embodiment. Varying the electrical potential(s) may move the ions between locations or states. In various embodiments, how to vary the electrical potential(s) may be defined by waveforms that specify one or more voltages to apply over a period of time. In various embodiments, the one or more voltage source 50 may be coupled to electrodes via circuitry. In various embodiments, the circuity coupling the voltage sources 50 the electrodes may be located outside the cryostat and/or vacuum chamber 40, inside the cryostat and/or vacuum chamber 40, or both inside and outside the cryostat and/or vacuum chamber 40. In various embodiments, the circuity coupling the voltage sources 50 to the electrodes will be comprised of circuit components capable of and/or configured to operate at the temperatures for their location, such as those in the cryostat and/or vacuum chamber, which may have temperatures below 4 Kelvin.

In some embodiments the computing entity 10 embodies one or more computing devices embodied in hardware, software, firmware, and/or any combination thereof. The computing entity 10 may be embodied by a user device configured to provide various functionality. In this regard, the computing entity 10 may embody a conventional computing environment that interacts with the quantum computer 110. Non-limiting examples of a computing entity 10 include a specially configured mobile device, tablet, smartphone, personal computer, laptop, enterprise terminal, and/or the like. In some embodiments, the computing entity 10 is configured entirely by specially configured software application(s) installed to and/or otherwise executable via the computing entity 10 to provide various functionality for accessing and/or otherwise controlling the quantum computer 110 as described herein. In various embodiments, the computing entity 10 is a conventional and/or classical computer.

In some embodiments, the computing entity 10 includes specially configured hardware, software, firmware, and/or a combination thereof, that enables access to and/or configuration of the quantum computer 110. In some embodiments, the computing entity 10 provides access to functionality for generating and/or retrieving a quantum program for execution via the controller 30 of the quantum computer 110. In this regard, the computing entity 10 may receive one or more user input(s) for constructing and/or that otherwise embody a quantum program to be executed. For example, a user of the computing entity 10 may interact with the computing entity 10 to construct a quantum circuit, store the quantum circuit, and submit the quantum circuit for execution via the controller of the quantum computer 110. In some embodiments, the computing entity 10 is embodied by a user-facing device of the quantum computer 110, for example such that communications can occur without requiring the network 20.

Additionally or alternatively, in some embodiments, the computing entity 10 enables user input and/or output for accessing the quantum computer 110 to execute a quantum program. In some embodiments, the computing entity 10 communicates with one or more computing devices of the quantum computer 110, such as a controller 30, which may generate and/or compile instructions for executing via a quantum computer 110.

Additionally or alternatively, a computing entity 10 is configured to allow a user to provide input to the quantum computer 110 (e.g., via a user interface of the computing entity 10) and receive, view, and/or the like output from the quantum computer 110.

In an example embodiment, the computing entity 10 may translate, configure, format, and/or the like information/data, quantum computing algorithms, quantum program, and/or the like into a computing language, executable instructions, command sets, and/or the like that the quantum system controller 30 can understand and/or implement. In various embodiments, one or more device(s) of the quantum computer 110 (e.g., controller 30) receive data from the computing device entity 10 that embodies the quantum program, instructions to be performed to manipulate the quantum computer, and/or the like.

Additionally or alternatively, in various embodiments, the controller 30 may receive the quantum program from the computing entity 10 and compile it to produce control system instructions embodying hardware manipulation instructions or machine code level commends configured to, when executed, cause the execution of the quantum program on a quantum computer. In various embodiments, the execution of a quantum program may include providing and/or controlling voltages to one or more electrodes.

In various embodiments, the controller 30 is embodied by one or more computing devices external from but communicable with the quantum computer 110. For example, the controller 30 may be embodied by a circuit compiler embodied in a dedicated computing system embodied in hardware, software, firmware, and/or a combination thereof internal or external to the quantum computer 110, dedicated hardware communicable with a quantum computer 110, software executing on a computing system communicable with the quantum computer 110, and/or the like.

In various embodiments, the controller 30 may embody a conventional computing system, for example specially configured via one or more specialized software application(s) to execute one or more process(es) that determine positions for the qubits at various time steps and/or instructions for repositioning the qubits to such position. For example, the controller 30 may determine position assignments for each qubit at various time steps, and/or instructions embodying gate and/or swap operations, which may cause the qubits to reach specific positions at each of the appropriate time steps.

In various embodiments, the quantum system controller 30 is configured to control the voltage sources 50, cryostat system and/or vacuum system controlling the temperature and pressure within the cryostat and/or vacuum chamber 40, manipulation sources 60, and/or other systems controlling various environmental conditions (e.g., temperature, pressure, and/or the like) within the cryostat and/or vacuum chamber 40 and/or configured to manipulate and/or cause a controlled evolution of quantum states of one or more atomic objects within the confinement apparatus. For example, the quantum system controller 30 may cause a controlled evolution of quantum states of one or more atomic objects within the confinement apparatus to execute a quantum program. For example, the quantum system controller 30 may cause a reading procedure (e.g., measurement operation) comprising coherent shelving to be performed, possibly as part of executing a quantum program. Additionally, the quantum system controller 30 is configured to communicate and/or receive input data from the optics collection system 70 and corresponding to the reading of the quantum state of qubits of the quantum computer 110. In various embodiments, the atomic objects confined within the confinement apparatus are used as qubits of the quantum computer 110.

FIG. 2 illustrates a schematic diagram of an optical package in accordance with one or more embodiments of the present disclosure. In various embodiments, an optical package 200 may be used to generate a stabilized laser beam for use in quantum computing applications. Various embodiments may also generate a stabilized laser beam that may be used in other applications. While various embodiments of the present disclosure are described herein, such as with the optical package 200, it will be readily appreciated that not all embodiments are expressly described and it will be readily appreciated that not all embodiments are expressly described. Thus it will also be appreciated that various embodiments may include additional or alternative components and/or circuitries, the described components and/or circuitries may be alternatively arranged, and/or the one or more of the described components and/or circuitries may be omitted.

The optical package 200 may include a frequency generator 202, a frequency splitter 206, a laser 210, an etalon 220, a wavemeter 230, temperature setpoint servo 240, a temperature controller 250, PDH circuitry 260, a PDH setpoint servo 270, and a PDH servo 280.

A frequency generator 202 may generate a frequency generator signal 204 at a specific frequency. The frequency generator signal 204 may be a radiofrequency (RF) signal. In various embodiments, the frequency generator 202 may generate a frequency generator signal 204 that has a frequency of 25 MHz.

A frequency splitter 206 may receive the frequency generator signal 204 and split the frequency generator signal 204 into two or more signals. For example, the frequency splitter 206 may split the frequency generator signal 204 into a first frequency signal 208A and a second frequency signal 208B. In various embodiments, the first frequency signal 208A and the second frequency signal 208B are the same, such as having the same frequency and amplitude. In various embodiments, the first frequency signal 208A and the second frequency signal 208B may have the same frequency but have different amplitudes. In various embodiments, the frequency splitter 206 may include one or more amplifiers and/or filters. The first frequency signal 208A may be transmitted from the frequency splitter 206 to the laser 210. The second frequency signal 208B may be transmitted from the frequency splitter 206 to the PDH circuitry 260.

A laser 210 may generate a laser beam. The laser 210 may receive the first frequency signal 208A and generate a laser beam based at least on the first frequency signal 208A. For example, various embodiments may have a first frequency signal 208A having a frequency of 25 MHz and the laser 210 may generate a laser beam with a frequency of 500 THz.

In various embodiments, the laser beam generated by the laser 210 may be transmitted to one or more components of the optical device 200. For example, the laser beam generated by the laser 210 may be transmitted as a first laser beam 212A to an etalon 220. The laser beam generated may also be transmitted as a second laser beam 212B to a wavemeter 230. In various embodiments, the first laser beam 212A and the second laser beam 212B may have the same characteristics. Alternatively, in various embodiments, the first laser beam 212A and the second laser beam 212B may have some characteristics (e.g., frequency) that are the same and some that are different (e.g., amplitude).

An etalon 220 is an optical device that may be used to generate a stabilized laser beam. An etalon 220 includes an optical cavity that may use interference and wavelength selection to generate a stabilized laser beam by selecting a wavelength or narrow range of wavelengths of light from a received laser beam, such as the first laser beam 212A. In selecting the wavelength, the etalon 220 may act as a filter, and the filtering is based at least on the optical cavity in which light reflects. By adjusting the optical cavity of the etalon 220, the etalon 220 may be tuned to generate the stabilized laser beam at the selected wavelength or range of wavelengths. The etalon 220, including the optical cavity, is sensitive to temperature adjustments, which may cause fluctuations to the etalon 220. Such fluctuations in the etalon 220 result in fluctuations to the laser beam output by the etalon 220. Wavelengths are related to frequencies and, thus, controlling the wavelength also controls the frequencies. In various embodiments, this value of the frequency of the laser output by the etalon 220 is set based at least on a frequency required to cause particular atomic or molecular transitions in a quantum computer. Variations in the etalon 220 are problematic because the optical cavity resonance has to not only be stable but also be at the correct frequency for generating the stabilized laser beam.

While the optical package 200 may hold, or attempt to hold, the etalon 220 at a constant temperature, the etalon 220 is sensitive to fluctuations in the environment, such as temperature fluctuations. These fluctuations in its environment, such as swings in ambient temperature or swings in ambient pressure, cause fluctuations in the etalon due to the sensitivity of the etalon 220, particularly the optical cavity. For example, various embodiments may require stabilizing the temperature within 300 microKelvin for the laser beam output by the etalon 220 to be at the required frequency. Fluctuations in the optical cavity of the etalon 220 result in optical detuning of the laser beam output by the etalon 220 to the required frequency. By utilizing one or more operations described herein, the etalon 220 may be used to generate a stabilized laser output as required by the quantum computer.

A stabilized laser beam generated by the etalon 220 may be transmitted to one or more other components of the optical package 200. In various embodiments, the stabilized laser beam 222 is transmitted to PDH circuitry 260. A stabilized laser beam is also transmitted to one or more other portions of a quantum computer to control the performance of one or more operations for controlling the state(s) of one or more qubits.

A wavemeter 230 is an optical instrument that measures the wavelength of laser beams. A wavemeter 230 provides a high precision measurement(s) of the wavelength of a received laser beam, such as the second laser beam 212B. The wavemeter 230 may generate one or more signals used to provide this measurement(s) to one or more other components of the optical package 200. The wavemeter 230 may generate communication signals and/or DC signals. In various embodiments, the communication signals may transmit data electronically at speeds above DC, such as in the kHz frequency range. The measurements of the wavemeter 230 are used to adjust a PDH setpoint used to lock the laser and generate a PDH error, which are used to provide adjustable reference control. The wavemeter 230 measurements may also be used to adjust temperature setpoints. Such adjustment to temperature setpoints may be used by the optical package for adjustable control of the laser 210 and or etalon 220 to generate a laser beam in a linear range of operation, which is further described herein.

A first wavemeter signal 232 may be a communication signal generated by the wavemeter 230 that is provided to a PDH setpoint servo 270. The first wavemeter signal 232 may be configured to provide the wavelength of the second laser beam 212B received by the wavemeter 230 from the laser 210. In various embodiments, the wavemeter 230 may have one or more communication modules that generate the first wavemeter signal 232 in a signal format configured to be received by the PDH setpoint servo 270. In various embodiments, the wavemeter 230 may be a “middle servo” that adjusts a DC setpoint for controlling the wavelength of the stabilized laser beam. In various embodiments, the PDH setpoint servo 270 may be integrated into or a part of the wavemeter 230. In such embodiments, the first wavemeter signal 232 is transmitted to the PDH setpoint servo 270 internally to the wavemeter 230.

A second wavemeter signal 234 may be a DC signal generated by the wavemeter 230 and may be provided to a temperature setpoint servo 240. In various embodiments, the second wavemeter signal 234 may be configured to provide the wavelength of the second laser beam 212B measured by the wavemeter and/or an offset measured by the wavemeter between the second laser beam 212B received and a wavelength setpoint.

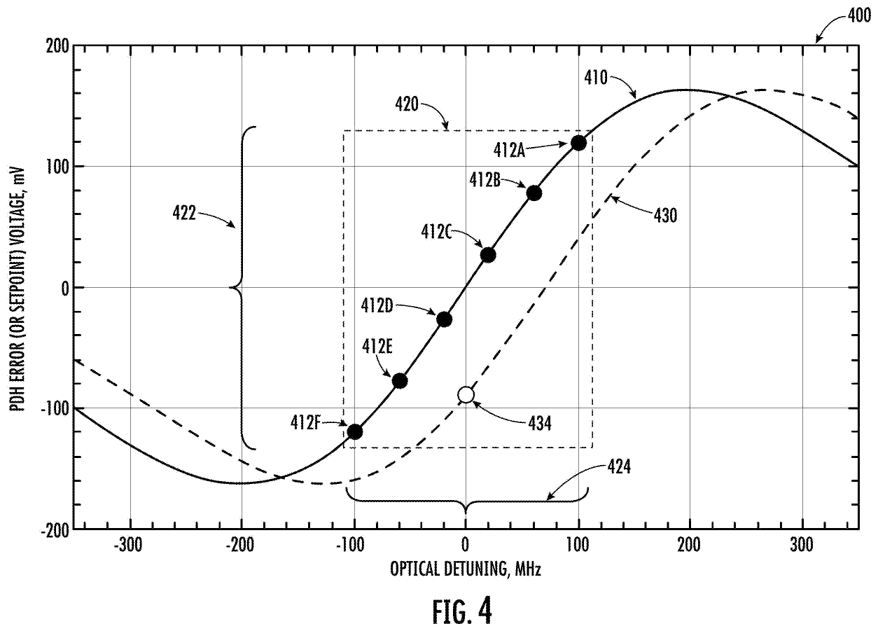

A temperature setpoint servo 240 may receive a second wavemeter signal 234 from the wavemeter 230. The temperature setpoint servo 240 may determine a temperature offset based at least on the second wavemeter signal 234. For example, various embodiments may have another servo (e.g., the PDH setpoint servo 270) pull a setpoint or lock point of a PDH lock signal away from a prior setpoint or lock point (e.g., a point on FIG. 4 associated with a PDH error of 0 mV) to maintain the correct frequency. Then there may be a temperature error of the etalon 220 (e.g., due to temperature fluctuation). The temperature setpoint servo 240 may determine a temperature offset to alter the temperature in response to the temperature error to lessen the lock point adjustment (e.g., from zero mV). Thus, the temperature setpoint servo 240 may be configured to adjust a temperature setpoint of a system and generate a temperature setpoint signal 242 that is transmitted to a temperature controller 250. The temperature setpoint may be set to correspond with a region of operation of the laser 210 associated with a linear response region. The temperature setpoint signal 242 may be a DC signal with a value (e.g., voltage value) associated with the setpoint of the temperature.

Note also that errors arising from sources other than temperature, e.g. from unwitting interferometers or from any other source, can also lead to the laser being locked at the wrong frequency, but this “middle servo” will also take care of these errors, so long as they are sufficiently slow and limited in effect.

A temperature controller 250 may receive a temperature setpoint signal 242 from the temperature setpoint servo 240. The temperature controller 250 may generate and transmit a temperature control signal 252 to control the temperature of the etalon 220 or an environment in which the etalon 220 is located. The temperature controller 250 may also receive one or more temperature control signals 252 from the etalon 220 or an environment the etalon is located in, such as an etalon temperature measurement signal that provides the current temperature of the etalon the environment.

The temperature controller 250 may control the temperature of an etalon 220, such as via control of the environment an etalon 220 is located in. In various embodiments, the environment may be an oven (not illustrated) that is used to control the temperature. Temperature control of the environment may be able to control the environment, but such heating and cooling of the environment is comparatively slow compared to electronic control of the laser 210.

The PDH circuitry 260 may include a plurality of electrical components and/or optical components. The PDH circuitry 260 may receive a stabilized laser beam 222 from an etalon 220 and a second frequency signal 208B from a frequency splitter 206. Alternatively, the frequency signal to the PDH circuitry 260 may be provided from a frequency generator 202. The PDH circuitry 260 may generate a PDH error signal 262 based at least on signals received. The PDH circuitry 260 may also generate a temperature control supply signal 264 based at least on received signals and transmit it to a temperature controller 250. Various embodiments of the PDH circuitry 260 and of generating a PDH error signal 262 are described further herein.

A PDH setpoint servo 270 may receive a first wavemeter signal 232 from the wavemeter 230. In various embodiments, the PDH setpoint servo 270 may be located in the wavemeter 230. The PDH setpoint servo 270 may generate a PDH setpoint signal 272 based at least on the first wavemeter signal 232, which may include a measurement of the wavelength of the second laser beam 212B. In various embodiments, the PDH setpoint servo 270 may include an integrator circuitry that accumulates a recent time history of error. To the extent the error (e.g., frequency error) is consistently biased away from zero (e.g., consistently positive or consistently negative), then the PDH setpoint servo 270 may make one or more adjustments to the PDH setpoint until an average of the recent time history of error approaches or reaches zero error. The PDH setpoint servo 270 may dynamically adjust the PDH setpoint used to lock the laser via the PDH setpoint signal 272. The PDH setpoint may be adjusted to correct the optical tuning of the laser 210 to keep the laser beam output of the optical package 200 stabilized, such as described with one or more operations described herein.

A PDH servo 280 may receive a first wavemeter signal 232 from the PDH circuitry 260 and a PDH setpoint signal 272 from a PDH setpoint servo 270. The PDH servo 280 may generate a PDH lock signal 282 based at least on the signals received, such as described with one or more operations described herein. The PDH lock signal 282 may be provided to the laser 210. The PDH lock signal 282 is an electrical signal based at least on a PDH lock setpoint. The laser 210 may use the PDH lock setpoint in the PDH lock signal 282 to generate a laser beam 212.

In various embodiments, the PDH error signal 262 may amount to a real-time measurement of the laser frequency relative to the stabilized laser beam 220 generated by the etalon 220. The PDH setpoint in the PDH set point servo 270 is a setpoint for where the laser 210 should lock to attain a correct frequency. The PDH servo 280 adjusts the laser frequency via the PDH setpoint signal 280 until the average error between the PDH lock setpoint and the laser frequency approaches or reaches zero, which is the laser 210 attaining or remaining on the correct frequency.

In various embodiments, the optical package 200 includes four (4) servos or controllers that allow for one or more feedback signals for dynamically controlling the optical package 200 and the generation of a stabilized laser beam. The temperature controller 250 may be or may include the first servo. The PDH servo 280 may be or may include the second servo. The PDH setpoint servo 270 may be or may include the third servo. The temperature setpoint servo 240 may be or may include the fourth servo. Adjustments to one or more of these servos may be used to provide improved dynamic adjustable control of an optical package 200 to stabilize a laser beam (e.g., 222) generated by the optical package 200.

For example, an optical package 200 may dynamically control adjustments via electrical control of the laser 210 with the PDH lock signal 282 at a frequency of 10, 20, 100, or more times a second. The dynamic control addresses temperature fluctuations (or other fluctuations) experienced by the etalon 220. The wavemeter 230 may be read for thermal control at a rate of 2, 3, or 4 times a second to thermally control the etalon 220 via the temperature controller 250. In such examples, temperature control is slower than electrical control and may not be sufficient to control the output of the laser 210 for addressing the fluctuations experienced by the etalon 220. As described herein, dynamically locking the laser may be done electronically at, for example, kHz rates. Thus, it may suppress the fluctuations that are not able to be suppressed by conventional temperature control.

While various embodiments of the present disclosure are described herein, such as with the optical package 200, it will be readily appreciated that not all embodiments are expressly described and it will be readily appreciated that not all embodiments are expressly described. For example, various embodiments include, among other things, a controlled device, an instrument device, a measurement device, and a control system. In various embodiments, the controlled device may be laser 210, the instrument device may be the etalon 220, the measurement device may be the wavemeter 230, and the control system may be comprised of a temperature setpoint servo 240, a temperature controller 250, PDH circuitry 260, a PDH setpoint servo 270, and a PDH servo 280.

The controlled device (e.g., laser 210) generates a controlled output (e.g., laser beam 212A) based at least on a setpoint (e.g., PDH lock) in a setpoint signal (e.g., PDH lock signal 282). The controlled output may be provided or transmitted to the instrument device (e.g., etalon 220). The setpoint is associated with the controlled output such that the controlled device may be controlled by the setpoint during operation of the controlled device, including to adjust the operation of the controlled device based on the setpoint. For example, the setpoint may be controlled to adjust the frequency of the laser 210 in response to a fluctuation in an environment of the etalon 220.

The instrument device (e.g., etalon 220) generates an instrument output (e.g., stabilized laser beam 222) based at least on the controlled output (e.g., laser beam_212A). The instrument device and/or the environment of the instrument device may also be controlled by the control system.

The measurement device (e.g., wavemeter 230) measures the controlled output (e.g., laser beam 212B) and generates a measurement output signal (e.g., first wavemeter signal 232). The measurement output signal may be provided or transmitted to the control system.

The control system may control the controlled device (e.g., laser 210) by performing one or more operations to, among other things, generate a setpoint signal (e.g., 282) that provides or transmits a setpoint to the controlled device (e.g., laser 210). Examples of these operations may include one or more of the following.

Generating an error signal based at least on the instrument output. The error signal may be at an error signal update rate that occurs with a second frequency. and the error signal may have a second accuracy. This error signal update rate may be faster than the measurement rate of a measurement of a measurement device. This second accuracy may be less accurate than a first accuracy of the measurement device. The error signal may have at least a portion that is monotonic.

Receiving the measurement output signal from the measurement device.

Generating a setpoint signal based at least on the measurement output signal. The setpoint signal may be associated with an offset related to the error signal. One or more changes to at least the measurement output signal may be associated with one or more adjustments in the setpoint signal.

Generating a control signal based at least on the error signal and the setpoint signal. The control signal may be generated based on at least the portion of the error signal that is monotonic.

Transmitting the control signal to the controlled device to control the controlled device.

Both the measurement output signal and the error signal may be associated with a controlled variable. In various embodiments, the controlled variable may be a frequency or wavelength, sometimes referred to as a controlled variable frequency or controlled variable wavelength. In various embodiments, the controlled variable frequency may be a frequency of the laser beam. In various embodiments, the controlled variable wavelength may be a wavelength of the laser beam. In various embodiments, the measurement device (e.g., wavemeter 230) may generate the measurement output signal with a first accuracy at a measurement rate of a first frequency. The control system may generate an error signal (e.g., PDH error signal 262) with a second accuracy at an error signal update rate of a second frequency. The first frequency of the measurement rate and the second frequency of the error signal update rate are different, and the first accuracy and the second accuracy are different.

For example, a wavemeter 230 may generate a wavemeter signal 232 measuring the wavelength and/or frequency of the laser beam 212B that is highly accurate but with a slower measurement rate. The PDH circuitry 260 of a control system may generate a PDH error signal 262 that is less accurate but is comparatively much faster with an error signal update rate that is faster than the measurement rate. In other words, a frequency of the error signal update rate is much faster than a frequency at which the measurement rates of the wavemeter 230 in the wavemeter signal 232 are generated. This may be because the wavemeter takes longer to take a measurement and generate the wavemeter signal 232. The associated PDH setpoint signal 272 generated by the PDH setpoint servo 270 may also generate and/or adjust the PDH setpoint signal 272 at the second frequency associated with measurement rate of the wavemeter 230. The control system may then control the laser 210 based at least on the faster error signal update rate associated with the PDH error signal 262 and the comparatively slower measurement rate frequency of the PDH setpoint signal 272. Thus, the laser 210 may be controlled based at least on both a faster but less accurate signal derived from the stabilized laser beam 222 and a slower but more accurate signal derived from the laser beam 212B.

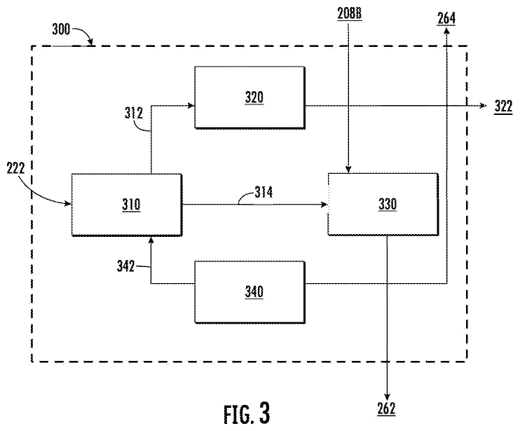

FIG. 3 illustrates a schematic diagram of a PDH circuitry in accordance with one or more embodiments of the present disclosure. In various embodiments, the PDH circuitry 260 may be the PDH circuitry 300 illustrated in FIG. 3. While various embodiments of the present disclosure are described herein, such as with the PDH circuitry 300, it will be readily appreciated that not all embodiments are expressly described and it will be readily appreciated that not all embodiments are expressly described. Thus it will also be appreciated that various embodiments may include additional or alternative components and/or circuitries, the described components and/or circuitries may be alternatively arranged, and/or the one or more of the described components and/or circuitries may be omitted.

The PDH circuitry 300 may include diplexer circuitry 310, a scope 320, a PDH controller 330, and a supply circuitry 340. In various embodiments, the scope 320 may be separate from the PDH circuitry 300.

A diplexer circuitry 310 may receive a stabilized laser beam 222 from the etalon 220. The diplexer circuitry 310 may diplex the received stabilized laser beam 222 into a DC light signal 312 and a diplexed RF signal 314. The DC light signal 312 may be at a lower frequency than the diplexed RF signal 314. The DC light signal 312 may be provided to a scope 320. The diplexed RF signal 314 may be provided to a PDH controller 330. In various embodiments, the diplexer circuitry 310 may include a diplexer, photodiodes, amplifiers, and/or additional electrical components.

A scope 320 may receive a DC light signal 312 from diplexer circuitry 310. In various embodiments, the scope 320 may be a picoscope. The scope 320 may generate one or more scope signals 322 that may be provided to a display (not illustrated) that may be used to show one or more waveforms.

A PDH controller 330 may receive a diplexed RF signal 314 from diplexer circuitry 310 and a second frequency signal 208B from a frequency splitter 206. The PDH controller may generate a PDH error signal 262 based at least on the received signals. The PDH error signal 262 may be generated according to the Pound-Drever-Hall (PDH) technique. The PDH error is a measure of how far the laser beam output by the etalon 220 is off resonance with the optical cavity of the etalon 220. The PDH error signal 262 may be a DC signal of a voltage associated with the PDH error determined by the PDH controller 330.

The PDH controller 330 may be controller as described elsewhere herein, including having a processor and/or memory configured to execute one or more operations, including the PDH technique for generating a PDH error. In various embodiments, the PDH controller 330 may have one or more software programs that generate the PDH error.

A supply circuitry 340 may provide a supply 342 to the diplexer circuitry 310. The supply circuitry 340 may also provide a temperature control supply signal 264 to the temperature controller 250. In various embodiments, the supply circuitry 340 may include a DC power supply, photodiodes, amplifiers, and/or additional electrical components.

FIG. 4 illustrates a graph of curves for PDH error versus optical detuning in accordance with one or more embodiments of the present disclosure. The x-axis of graph 400 is the optical detuning in MHz and the y-axis is the PDH error voltage in mV. It will be appreciated that the PDH error may be measured in other units. Alternatively, in various embodiments, the y-axis may be a PDH setpoint. Curve 410 is an example of a zero-crossing curve where the curve is set to cross the 0 value of the x-axis and the 0 value of the y-axis. Curve 430 is an example of a shifted curve resulting from a dynamic adjustment of the control of the optical package 200.

Conventional systems using PDH error for control with an optical package lock the PDH error and the optical detuning to the zero crossing. This does not allow for the dynamic control of the present disclosure.

In the present disclosure, dynamic control is provided that does not lock the PDH error to zero. Instead, the PDH error (or PDH setpoint) is allowed to be adjusted by floating the PDH error within a tuning range. The detuning of the second laser beam 212B from the resonance of the optical cavity of the etalon 220 may have a linear relationship to the PDH error for a range of frequencies for optical detuning.

This may be viewed in the graph by floating the PDH error up or down. Potential points that the PDH error may be allowed to be adjusted to are illustrated at points tuning points 412A to 412F. In various embodiments, by adjusting the PDH setpoint to one of the tuning points 412 provides for dynamic control of the laser 210 to compensate for fluctuations in the etalon 220.

An example of dynamic control being applied is illustrated with curve 430 where the PDH error (or PDH setpoint) has been adjusted to −90 mV. This adjustment is illustrated with a shift of the curve 410 to the right to become curve 430 that has an optical detuning at 0 MHz.

It will be appreciated that the graph 400 is illustrative to relative positions of what is measured on the axes. While the y-axis is illustrated as PDH error or PDH setpoint, these are related. If the PDH setpoint is adjusted to −90 mV, then a PDH error of −90 measured before the adjustment would subsequently meet the PDH setpoint after adjustment such that there is no PDH error. Thus, the graph illustrated is demonstrative of how PDH setpoint or PDH error may be displayed.

As illustrated in FIG. 4, the curve 410 of the PDH error to optical detuning has a symmetry at the resonance center at PDH error of 0. This range of frequencies along curve 410 having a linear response is illustrated in a linear region 420. In the linear region 420, while the response (e.g., curve) is not exactly linear, the curve is substantially linear. This linear portion is a tuning range. In various embodiments, the linear portion of the curve 410 may correspond to the full width at half maximum (FWHM) of the curve, which may be a little more than half of that frequency span.

Tuning range 422 of the linear region 420 is associated with the range of PDH errors (or PDH setpoints) of the linear region 420. Detuning range 424 of the linear region 420 is associated with the range of optical detuning frequencies of the linear region 420. The dynamically adjustable tuning of the optical package 200 may control the laser 210 within the tuning range to utilize the linear response of the optical package 200 within these ranges, which adjusts the first laser beam 212A provided to the etalon 220 to compensate for fluctuations in the etalon 220.

The measurement of PDH error and adjustment of PDH setpoint are electrical controls that may be adjusted quickly. The PDH error voltage associated on the y-axis of the graph 400 is a voltage transmitted in the PDH error signal 262 that corresponds to a PDH error determined by the PDH circuitry 260, particularly the PDH controller 330.

The dynamic tuning uses the linear slope region in the linear region 420 by using the PDH lock signal 282 provided to the laser 210 as an electrically-tunable offset. This allows for dynamic adjustment or floating the setpoint of the optical frequency lock to an appropriately offset voltage that is nearby, but not necessarily at, the center of the resonance of the optical cavity of the etalon 220, which is associated with optical detuning of 0.

The linear slope region illustrated is an example of a monotonic response to a controlled variable. It will be appreciated that the curve 410 has a roughly linear shape in the linear slop region even if it is not perfectly linear. While is it roughly linear, the shape is at least monotonic. Specifically, the curve 410 illustrated has a monotonic response in the linear region 420 (and curve 430 has a monotonic response too, though in its own linear region not illustrated). This monotonic response consistently increases (or decreases) over this region without fluctuations that increasing (or decreasing).

Changing the PDH setpoint is an electrical process. This electrical process for control provides many improvements, including being faster than adjustments using a thermal process.

In operation, if an optical resonance frequency of the etalon 220 changes and there is optical detuning (e.g., during a temperature fluctuation), then dynamic control provides for adjustment of the reference by (as illustrated with the graph 400) moving the curve to the left or right so that optical detuning of a stabilized laser beam 222 may be avoided. In various embodiments, if a curve is drifting outside the linear region 420, then temperature controller 250 may also be used to shift the curve back into the linear region 420.

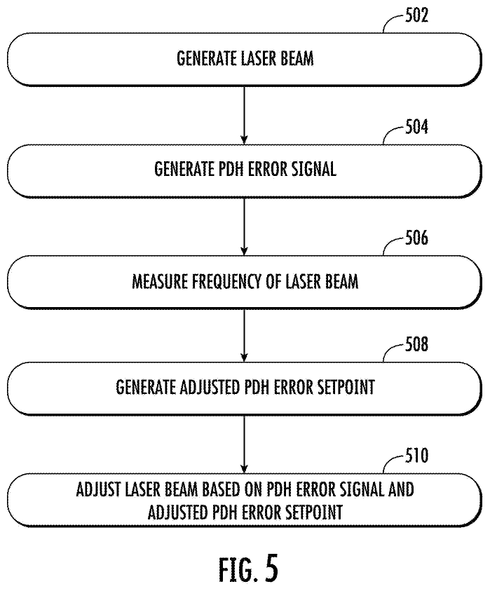

FIG. 5 illustrates a flowchart of example operations for controlling a laser beam in accordance with one or more embodiments of the present disclosure. One or more operations described herein provide for specific wavelength control of a laser, including control of a laser using an adjustable reference. The adjustable reference control provides for controlling the laser based at least on a temperature requirement and a PDH error signal that provide for dynamic control. While various embodiments of the present disclosure are described herein, such as with operations for controlling a laser beam, it will be readily appreciated that not all embodiments are expressly described. Thus it will also be appreciated that various embodiments may include additional or alternative operations for controlling a device via a control system.

At operation 502, a laser beam is generated. In various embodiments, a laser 210 is controlled to generate a laser beam 212. The laser 210 may generate the laser beam 212 based at least on a frequency and a PDH lock setpoint. The frequency may be received via a first frequency signal 208A received from a frequency splitter 206, which is based at least on a frequency generator signal 204 received from a frequency generator 202. The PDH lock setpoint may be received in a PDH lock signal 282 from a PDH servo 280. The laser beam 212 may be split into a plurality of laser beams, including a first laser beam 212A that is provided to an etalon 220 and a second laser beam 212B that is provided to a wavemeter 230. The etalon 220 generates and outputs a stabilized laser beam 222 that is based at least on the optical cavity of the etalon 220.

At operation 504, a PDH error signal is generated. In various embodiments, the stabilized laser beam 222 from the etalon 220 is provided to PDH circuitry 260. The PDH circuitry 260 measures the PDH error using the PDH technique and generates a PDH error signal 262 that is provided to PDH servo 280.

At operation 506, frequency of the laser beam is measured. In various embodiments, the wavemeter 230 receives the second laser beam 212B and measures the frequency of the second laser beam 212B. The wavemeter 230 generates a first wavemeter signal 232 that is provided to a PDH setpoint servo 270.

At operation 508, an adjusted PDH setpoint is generated. In various embodiments, the PDH setpoint servo 270 determines a PDH setpoint and generates a PDH setpoint signal 272 that transmits the PDH setpoint to the PDH servo 280.

At operation 510, a laser beam is adjusted based at least on PDH error signal and adjusted PDH setpoint. In various embodiments, the PDH servo 280 generates and/or adjusts a PDH lock signal 282 to control and adjust the control of the laser 210. During an initial calibration an initial PDH lock setpoint may be specified or programmed into the PDH servo 280. During operation, the PDH setpoint servo 270 adjusts the PDH lock setpoint based at least on the PDH error received in the PDH error signal 262 and the PDH setpoint received in the PDH setpoint signal 272. The adjustment of the PDH lock setpoint may be to minimize optical detuning when there are temperature fluctuations.

Thus, the PDH servo 280 receives the PDH error signal 262 and the PDH setpoint signal 272 and controls or adjusts control for the optical detuning. The dynamically controlled PDH setpoint transmitted in the PDH setpoint signal 272 is kept in a tuning range where the curve is generally a linear response. In other words, it is kept in a range in the linear region 420, which may be referred to as a locking region. In the locking region, the PDH setpoint may be chosen anywhere along linear response curve (e.g., anywhere along curve 410). This dynamic adjustability of the PDH setpoint set over the linear portion of the linear response curve expands the tolerance for temperature fluctuations and allows for faster control than changing the temperature of the environment.

While the method described in the present disclosure uses PDH error as an example feedback for adjustable reference control, it will be appreciated that methods described herein may also be used for adjustable control with other methods having a roughly linear error discriminator, which for optical frequency locking applications may include dither locking, Hansch-Coulliard techniques, tilt-locking, or the like. Additionally, it may also be applied to other types of locks outside of laser frequency stabilization, including RF phase locking. Further, the method may also be used for nonlinear adjustment control when the nonlinear regions may be linearized, such as with linearized error signals that are not intrinsically linear, which may increase the locking range without loss of servo stability.

As a further example, various embodiments include operations for controlling a controlled device via a control system. Such operations may include one or more of the following.

Generating an error signal based (e.g., PDH error signal 262) at least on the instrument output (e.g., stabilized laser beam 222). The error signal may have an update rate. This may be referred to as an error signal update rate that is at a particular frequency or time between updates. The error signal has an accuracy. The error signal may have at least a portion that is monotonic.

Receiving the measurement output signal (e.g., a first wavemeter signal 232 associated with a measured frequency of a laser beam 212B) from the measurement device (e.g., a wavemeter 230).

Generating the setpoint signal (e.g., PDH lock signal 282) based at least on the measurement output signal (e.g., first wavemeter signal 232). The setpoint signal may be associated with an offset related to the error signal.

Generating a control signal (e.g., PDH lock signal 282) to control the controlled device (e.g., laser 210) based at least on the error signal (e.g., PDH error signal 262) and the setpoint signal (e.g., PDH setpoint signal 272). The control signal may be generated based on the portion of the error signal that is monotonic.

Transmitting the control signal (e.g., PDH lock signal 282) to the controlled device (e.g., laser 210) to control the controlled device.

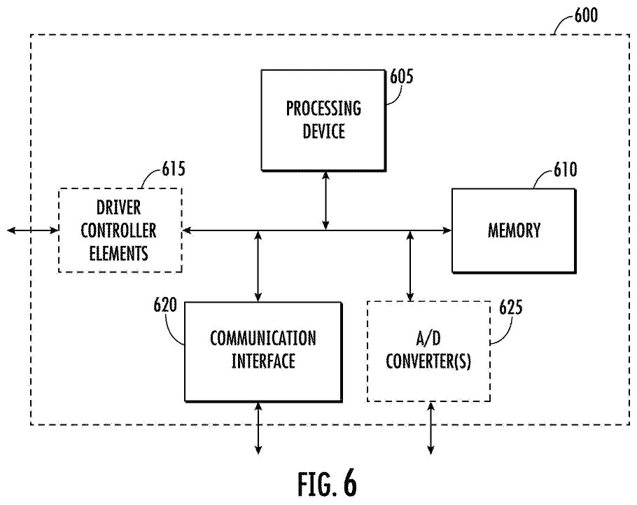

FIG. 6 illustrates a schematic diagram of a controller in accordance with one or more embodiments of the present disclosure. While various embodiments of the present disclosure are described herein, such as with the controller 600, it will be readily appreciated that not all embodiments are expressly described and it will be readily appreciated that not all embodiments are expressly described. Thus it will also be appreciated that various embodiments may include additional or alternative components and/or circuitries, the described components and/or circuitries may be alternatively arranged, and/or the one or more of the described components and/or circuitries may be omitted.

The controller 600 may comprise various controller elements including one or more processing devices 605, memory 610, driver controller elements 615, a communication interface 620, analog-digital converter elements 625, and/or the like.

For example, the one or more processing devices 605 may comprise one or more processing elements such as programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. The term circuitry may refer to an entirely hardware embodiment or a combination of hardware and computer program products.

For example, the memory 610 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In an example embodiment, execution of at least a portion of the computer program code stored in the memory 610 (e.g., by a processing device 605) causes the controller 600 to perform one or more operations, steps, processes, procedures and/or the like described herein.

In various embodiments, the driver controller elements 615 may include one or more drivers and/or controller elements each configured to control one or more drivers. In various embodiments, the driver controller elements 615 may comprise drivers and/or driver controllers. For example, the driver controllers may be configured to cause one or more corresponding drivers to be operated in accordance with executable instructions, commands, and/or the like scheduled and executed by the controller 600 (e.g., by the processing device 605). In various embodiments, the driver controller elements 615 may enable the controller 600 to perform one or more operations. The controller 600 may comprise one or more analog-digital converter elements 625 configured to receive signals or transmit signals.

In various embodiments, the controller 600 may comprise a communication interface 620 for interfacing and/or communicating with one or more computing entities 10. For example, the controller 600 may comprise a communication interface 620 for receiving executable instructions, command sets, and/or the like from the computing entity 10 and providing output to the computing entity 10. In various embodiments, the computing entity 10 and the controller 600 may communicate via a direct wired and/or wireless connection and/or one or more wired and/or wireless networks 20.

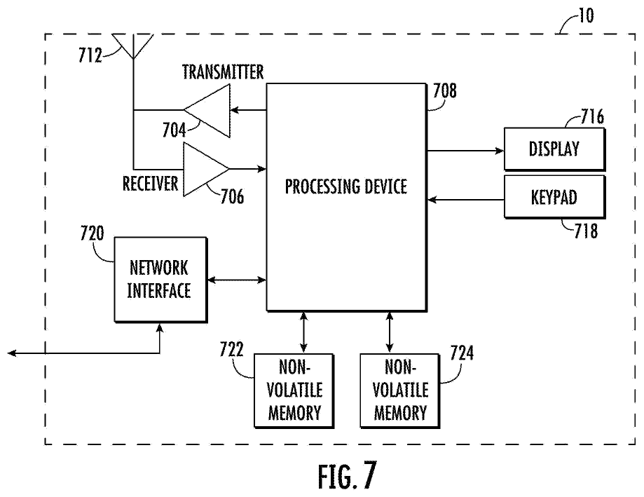

FIG. 7 illustrates a schematic diagram of an example classical computing entity in accordance with one or more embodiments of the present disclosure. In various embodiments, a computing entity 10 is configured to allow a user to provide input to the quantum computer 110 (e.g., via a user interface of the computing entity 10) and receive, display, analyze, and/or the like output from the quantum computer 110. A computing entity 10 can include an antenna 712, a transmitter 704 (e.g., radio), a receiver 706 (e.g., radio), and a processing device 708 that provides signals to and receives signals from the transmitter 704 and receiver 706, respectively. While various embodiments of the present disclosure are described herein, such as with the computing entity 10, it will be readily appreciated that not all embodiments are expressly described and it will be readily appreciated that not all embodiments are expressly described. Thus it will also be appreciated that various embodiments may include additional or alternative components and/or circuitries, the described components and/or circuitries may be alternatively arranged, and/or the one or more of the described components and/or circuitries may be omitted.

The signals provided to and received from the transmitter 704 and the receiver 706, respectively, may include signaling information/data in accordance with an air interface standard of applicable wireless systems to communicate with various entities, such as a controller 600, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

In various embodiments, the computing entity 10 further comprises one or more network interfaces 720 configured to communicate via one or more wired and/or wireless networks 20.

The computing entity 10 may also comprise a user interface device comprising one or more user input/output interfaces (e.g., a display 716 and/or speaker/speaker driver coupled to a processing device 708 and a touch screen, keyboard, mouse, and/or microphone coupled to a processing device 708). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 718 (hard or soft), a touch display, voice/speech or motion interfaces, scanners, readers, or other input device. In embodiments including a keypad 718, the keypad 718 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 722 and/or non-volatile storage or memory 724, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### Conclusion

It should be readily appreciated that the embodiments of the systems and apparatuses, described herein may be configured in various additional and alternative manners in addition to those expressly described herein. While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a computer-implemented process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this detailed description has set forth some embodiments of the present invention, the appended claims cover other embodiments of the present invention which differ from the described embodiments according to various modifications and improvements.

1. An apparatus comprising:
a controlled device configured to generate a controlled output based at least on a control signal;
an instrument device configured to receive the controlled output and to generate an instrument output based on the controlled output;
a measurement device configured to measure the controlled output at a measurement rate and a first accuracy and to generate a measurement output signal;
a control system to control the controlled device and configured to:
generate an error signal at an error signal update rate and a second accuracy based at least on the instrument output, wherein at least a portion of the error signal is monotonic, wherein the error signal update rate is faster than the measurement rate, and wherein the first accuracy is more accurate than the second accuracy;
generate a setpoint signal based at least on the measurement output signal, wherein the setpoint signal is associated with an offset related to the error signal; and
generate the control signal to control the controlled device based at least on the at least the portion of the error signal that is monotonic and the setpoint signal.

2. The apparatus of claim 1, wherein the controlled device is a laser;
wherein the controlled output is a laser beam;
wherein the control signal is a PDH lock signal;
wherein the instrument device is an etalon;
wherein the instrument output based on the controlled output is a stabilized laser beam;
wherein the measurement device is a wavemeter;
wherein the measurement output signal is a first wavemeter signal associated with a wavelength of the laser beam;
wherein the control system is comprised of a PDH circuitry, a PDH setpoint servo, a PDH servo;
wherein PDH circuitry of the control system is configured to generate the error signal of a PDH error signal;
wherein the PDH setpoint servo of the control system is configured to generate the setpoint signal of a PDH setpoint signal; and
wherein the PDH servo of the control system is configured to generate the control signal of the PDH lock signal based at least on the portion of the PDH error signal that is monotonic and the PDH setpoint signal.

3. The apparatus of claim 2, wherein the PDH circuitry is comprised of:
a diplexer circuitry configured to receive the stabilized laser beam from the etalon and diplex the stabilized laser beam into a plurality of signals including a diplexed RF signal; and
a PDH controller configured to receive the diplexed RF signal and generate the PDH error signal.

4. The apparatus of claim 2, wherein to adjust the PDH lock signal is based at least on one or more changes in the PDH setpoint signal associated with adjusting the offset of a PDH setpoint within a linear region of the portion of the PDH error signal that is monotonic.

5. The apparatus of claim 2, further comprising a temperature controller configured to control a temperature of an environment of the etalon.

6. The apparatus of claim 5, wherein the temperature controller is configured to control the temperature of the environment of the etalon based at least on a temperature setpoint signal; and
wherein the temperature setpoint signal is generated by a temperature setpoint servo based at least on a second wavemeter signal generated by the wavemeter.

7. The apparatus of claim 2, further comprising a frequency generator configured to generate a frequency signal; and
wherein the laser is further configured to generate the laser beam also based at least on the frequency signal.

8. A system comprising:
an apparatus to receive an instrument output;
a controlled device configured to generate a controlled output based at least on a control signal;
an instrument device configured to receive the controlled output and to generate an instrument output based on the controlled output;
a measurement device configured to measure the controlled output at a measurement rate and a first accuracy and to generate a measurement output signal;
a control system to control the controlled device and configured to:
generate an error signal at an error signal update rate and a second accuracy based at least on the instrument output, wherein at least a portion of the error signal is monotonic, wherein the error signal update rate is faster than the measurement rate, and wherein the first accuracy is more accurate than the second accuracy;
generate a setpoint signal based at least on the measurement output signal, wherein the setpoint signal is associated with an offset related to the error signal; and
generate the control signal to control the controlled device based at least on the at least the portion of the error signal that is monotonic and the setpoint signal.

9. The system of claim 8, wherein the system is a quantum computing system;
wherein the apparatus is a confinement apparatus;
wherein the controlled device is a laser;
wherein the controlled output is a laser beam;
wherein the control signal is a PDH lock signal;
wherein the instrument device is an etalon;
wherein the instrument output based on the controlled output is a stabilized laser beam;
wherein the measurement device is a wavemeter;
wherein the measurement output signal is a first wavemeter signal associated with a wavelength of the laser beam;
wherein the control system is comprised of a PDH circuitry, a PDH setpoint servo, a PDH servo;
wherein PDH circuitry of the control system is configured to generate the error signal of a PDH error signal;
wherein the PDH setpoint servo of the control system is configured to generate the setpoint signal of a PDH setpoint signal;
wherein the PDH servo of the control system is configured to generate the control signal of the PDH lock signal based at least on the portion of the PDH error signal that is monotonic and the PDH setpoint signal; and
wherein the PDH servo is further configured to adjust the PDH lock signal based at least on one or more changes in the PDH setpoint signal associated with changes in the first wavemeter signal, and an adjustment to the PDH lock signal is associated with a fluctuation in an environment the etalon is located in.

10. The system of claim 9, wherein the PDH circuitry is comprised of:
a diplexer circuitry configured to receive the stabilized laser beam from the etalon and diplex the stabilized laser beam into a plurality of signals include a diplexed RF signal; and
a PDH controller configured to receive the diplexed RF signal and generate the PDH error signal.

11. The system of claim 9, wherein to adjust the PDH lock signal based at least on one or more changes in the PDH setpoint signal is associated with adjusting the offset of a PDH setpoint within a linear region associated with a linear response of the stabilized laser beam to the adjustment.

12. The system of claim 9, further comprising a temperature controller configured to control a temperature of the environment of the etalon.

13. The system of claim 12, wherein the temperature controller is configured to control the temperature of the environment of the etalon based at least on a temperature setpoint signal; and
wherein the temperature setpoint signal is generated by a temperature setpoint servo based at least on a second wavemeter signal generated by the wavemeter.

14. The system of claim 9, further comprising a frequency generator configured to generate a frequency signal; and
wherein the laser is further configured to generate the laser beam also based at least on the frequency signal.

15. A method comprising:
generating, with a controlled device, a controlled output based at least on a setpoint in a control signal;
generating, with an instrument device, an instrument output based at least on the controlled output;
generating, with a measurement device, a measurement output signal associated with a controlled variable of the controlled output, wherein the measurement output signal has a measurement rate and a first accuracy;
generating, with a control system, an error signal based at least on the instrument output, wherein the error signal has an error signal update rate and a second accuracy, wherein at least a portion of the error signal is monotonic, wherein the error signal update rate is faster than the measurement rate, and wherein the first accuracy is more accurate than the second accuracy;
generating, with the control system, a setpoint signal based at least on the measurement output signal, wherein the setpoint signal is associated with an offset related to the error signal; and
generating, with the control system, the control signal based at least on the error signal and the setpoint signal.

16. The method of claim 15, wherein the controlled device is a laser;
wherein the controlled output is a laser beam;
wherein the control signal is a PDH lock signal;
wherein the instrument device is an etalon;
wherein the instrument output based at least on the controlled output is a stabilized laser beam;
wherein the measurement device is a wavemeter;
wherein the measurement output signal is a first wavemeter signal associated with a wavelength of the laser beam;
wherein the control system is comprised of a PDH circuitry, a PDH setpoint servo, a PDH servo;
wherein generating the error signal is generating, by the PDH circuitry, the error signal of a PDH error signal;
wherein generating the setpoint signal is generating, by the PDH setpoint servo, the setpoint signal of a PDH setpoint signal;
wherein generating the control signal is generating, by the PDH servo, the control signal of the PDH lock signal based at least on the portion of the PDH error signal that is monotonic and the PDH setpoint signal; and
wherein the method further comprises:
adjusting, by the PDH servo, the PDH lock signal based at least on one or more changes in the PDH setpoint signal associated with changes in the first wavemeter signal, wherein an adjustment to the PDH lock signal is associated with a fluctuation in an environment the etalon is located in.

17. The method of claim 16, wherein the PDH circuitry is comprised of a diplexer circuitry and a PDH controller; and
wherein the method further comprises:
diplexing, with the diplexer circuitry, the stabilized laser beam from the etalon into a plurality of signals including a diplexed RF signal; and
generating, with the PDH controller, the PDH error signal based as least one the diplexed RF signal.

18. The method of claim 16, wherein adjusting the PDH lock signal is based at least on one or more changes in the PDH setpoint signal associated with adjusting the offset of a PDH setpoint within a linear region associated with a linear response of the stabilized laser beam to the adjustment.

19. The method of claim 16, further comprising controlling, with a temperature controller, a temperature of the environment of the etalon.

20. The method of claim 19, wherein controlling the temperature is based at least on a temperature setpoint signal generated by a temperature setpoint servo based at least on a second wavemeter signal generated by the wavemeter.
